(19) United States
(12) Patent Application Publication
(10) Pub. No.: US 2012/0049696 A1
(43) Pub. Date: Mar. 1, 2012

(54) PIEZOELECTRIC DEVICE USING NANOPORE AND METHOD OF MANUFACTURING THE SAME

(75) Inventors: Seung-Nam CHA, Seoul (KR); Byoung-Lyong CHOI, Seoul (KR); Byong-Gwon SONG, Seoul (KR)

(73) Assignee: SAMSUNG ELECTRONICS CO., LTD., Suwon-si (KR)

(21) Appl. No.: 13/035,495

(22) Filed: Feb. 25, 2011

(30) Foreign Application Priority Data
Aug. 30, 2010 (KR) 10-2010-0084038

(51) Int. Cl. H01L 41/04; H01L 41/22

(52) U.S. Cl. 310/367; 29/25.35

(57) ABSTRACT

A piezoelectric device including an engraved nanostructure body and a method of manufacturing the same are provided. The piezoelectric device includes a matrix including a piezoelectric material, a nanopore may be disposed in the matrix, and the nanopore may be extended substantially in a predetermined direction. The method may include coating a piezoelectric material on a substrate having a nanostructure body disposed thereon, and selectively etching the nanostructure body.

### CROSS-REFERENCE TO RELATED APPLICATION

This application claims priority from Korean Patent Application No. 10-2010-0084038 filed in the Korean Intellectual Property Office on Aug. 30, 2010, the entire disclosure of which is incorporated herein by reference.

### BACKGROUND

1. Field

The following disclosure relates to a piezoelectric device using a nanopore and a method of manufacturing the same.

2. Description of the Related Art

A piezoelectric device is a device for converting mechanical vibration into electrical energy. For example, electrical energy in the form of a charge behavior is caused by a piezoelectric potential generated by mechanical vibration applied to the piezoelectric device. The piezoelectric device may be utilized in a sensor sensing mechanical vibration, another type of sensor, an energy source for a small device or the like, or may be used in energy harvesting.

A piezoelectric device having a nanostructure may improve piezoelectric efficiency due to a strain confinement effect of the nanostructure.

For example, a piezoelectric device having a bulky structure distributes the strain generated by one-direction stress in various directions, while on the other hand, a piezoelectric device having a nanostructure such as a nanowire may improve piezoelectric efficiency since the strain is limited in the longitudinal direction of the nanowire.

Therefore, research on piezoelectric devices including nanostructures has been performed in order to improve the piezoelectric efficiency of piezoelectric devices.

### SUMMARY

One or more embodiments provide a piezoelectric device having a novel nanostructure, improved performance, and/or a highly efficient piezoelectric material, and a method of manufacturing the same.

According to an aspect of an embodiment, a piezoelectric device may be an engraved nanostructure body. For example, the piezoelectric device may include a matrix including a piezoelectric material. At least one nanopore may be disposed in the matrix, and the nanopore may extend substantially in a predetermined direction.

A plurality of nanopores may be disposed in the matrix, and each of the plurality of nanopores may extend substantially in a predetermined direction.

The at least one nanopore may have a nanowire shape, a nanoribbon shape, or the like.

The at least one nanopore may be hollow.

The matrix may include at least one highly efficient piezoelectric material. For example, the matrix may include PZT (lead zirconate titanate, Pb[ZrₓTi₁₋ₓ]O₃, 0<x<1), PVDF (polyvinylidene fluoride), BTO (barium titanate, BaTiO₃), or the like.

In addition, the matrix may include at least one piezoelectric material that is easily processed into a nanowire. Examples of such a piezoelectric material include, but are not limited to, ZnO (zinc oxide), silicon (Si), carbon nanotubes, and the like.

According to an aspect of another embodiment, a method of manufacturing a piezoelectric device may include coating a piezoelectric material on a substrate having at least one nanostructure body disposed thereon, and selectively etching the nanostructure body.

The at least one nanostructure body may extend substantially in a predetermined direction. In addition, a plurality of nanostructure bodies may be disposed on the substrate, and each of the plurality of nanostructure bodies may extend substantially in the predetermined direction.

The at least one nanostructure body may have a nanowire shape, a nanoribbon shape, or the like.

The nanostructure body may include at least one of ZnO, silicon (Si), carbon nanotubes, and the like.

The matrix may be formed by a coating process, and a nanopore may be formed by an etching process.

A method of manufacturing a piezoelectric device may further include forming the at least one nanostructure body on the substrate. For example, the nanostructure body may be formed by a thermal chemical vapor deposition (CVD) method, a hydrothermal method, or the like.

The piezoelectric material may include at least one of lead zirconate titanate, Pb[ZrₓTi₁₋ₓ]O₃, 0<x<1), polyvinylidene fluoride, barium titanate, BaTiO₃, and the like.

### BRIEF DESCRIPTION OF THE DRAWINGS

The above and/or other aspects will become apparent and more readily appreciated from the following description of the embodiments, taken in conjunction with the accompanying drawings of which:

FIG. 1 is a schematic perspective view of a piezoelectric device according to an embodiment;

FIG. 2 is a view showing a process of manufacturing a piezoelectric device according to an embodiment;

FIG. 3 is a view showing a process of manufacturing a piezoelectric device according to an embodiment;

FIG. 4 is a graph showing piezoelectric potential depending upon a gap between nanopores in the piezoelectric device according to an embodiment;

FIG. 5 is a view modeling a piezoelectric device having a bulky structure; and

FIG. 6 is a view modeling a piezoelectric device having a nanostructure.

### DETAILED DESCRIPTION

Hereinafter, embodiments of this disclosure are described in detail. This disclosure may, however, be embodied in many different forms and should not be construed as limited to the embodiments set forth herein.

In drawings, in order to describe the embodiments explicitly, some elements are not depicted. Like reference numerals designate the same or similar elements throughout the specification. Well-known techniques are not described in detail. Generally well-known technologies are not described in detail.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Further, when an element is referred to as being “directly under” another element, there are no intervening elements present.

As used herein, the terms “a” and “an” are open terms that may be used in conjunction with singular items or with plural items.

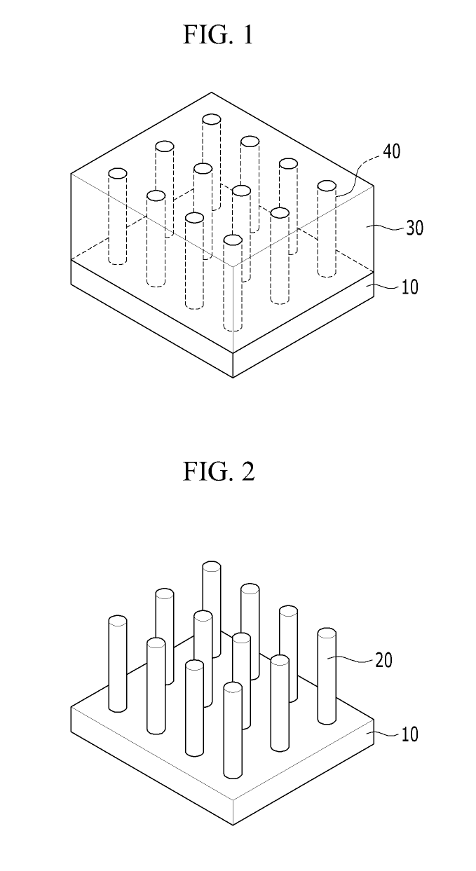

A piezoelectric device according to an embodiment is described in detail with reference to FIG. 1.

FIG. 1 is a schematic perspective view of a piezoelectric device according to an embodiment.

The piezoelectric device may be an engraved nanostructure body. For example, the piezoelectric device includes a matrix 30 including a piezoelectric material, and nanopores 40 disposed in the matrix 30. The matrix 30 may be disposed on a substrate 10.

The nanopores 40 may extend in substantially one direction. The nanopores 40 may be shaped in the form of nanowires, nanoribbons, or the like. Referring to FIG. 1, the nanopores 40 may be hollow and cylindrical, and a plurality of nanopores 40 may extend in substantially one direction. Furthermore, the nanopores 40 may have various shapes. For example, the nanopores 40 may have cross-sections in the shape of a circle, a quadrangle, a polygon, an oval or the like, and the cross-sections of the nanopores 40 may not be uniform in a length direction of the nanopores 40.

The matrix 30 includes at least one piezoelectric material. For example, the piezoelectric material may be a highly efficient piezoelectric material. The piezoelectric material may include, but is not limited to, PZT (lead zirconate titanate, Pb[ZrₓTi₁₋ₓ]O₃ 0<x<1), PVDF (polyvinylidene fluoride), BTO (barium titanate, BaTiO₃) or the like.

When a piezoelectric device is fabricated using the piezoelectric material of PZT, PVDF, BTO, or the like, it may be difficult to provide a piezoelectric device with a nanostructure such as nanowire, nanoribbon, or the like. In addition, even if the piezoelectric device having nanowire is fabricated using a piezoelectric material of PZT, PVDF, BTO, or the like, it may be difficult to control the direction of the plurality of nanowires.

However, according to an aspect of this embodiment, the piezoelectric device has an engraved nanostructure including a matrix 30 formed with nanopores 40. Accordingly, a piezoelectric device having a new nanostructure and including a piezoelectric material of PZT, PVDF, BTO, or the like may be provided. In addition, the nanopores 40 are provided using a piezoelectric material capable of easily forming a nanostructure such as a nanowire or the like, so the direction of a plurality of nanopores 40 may be easily controlled. Thereby, a piezoelectric device according to this embodiment may improve piezoelectric efficiency due to the strain confinement effect of the nanostructure, and furthermore it may improve the piezoelectric performance.

It may further include at least one piezoelectric material capable of easily forming a nanostructure such as a nanowire. Examples thereof may include, but are not limited to, ZnO (zinc oxide), silicon (Si), carbon nanotubes, or the like.

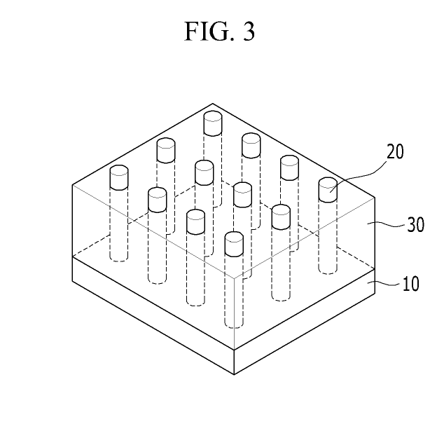

Hereinafter, a method of manufacturing a piezoelectric device according to an embodiment is described in detail with reference to FIGS. 2 and 3.

FIG. 2 is a view showing a process of providing a piezoelectric device according to one embodiment, and FIG. 3 is a view showing a process of providing a piezoelectric device according to one embodiment.

Referring to FIG. 2, at least one nanostructure body 20 is formed on a substrate 10. The nanostructure body 20 may extend in substantially one direction. In addition, when a plurality of nanostructure bodies 20 are disposed on the substrate 10, the plurality of nanostructure bodies 20 may be extended in substantially one direction. The nanostructure bodies 20 have the shape of a nanowire, a nanoribbon, or the like. The nanostructure bodies 20 may include at least one piezoelectric material capable of easily forming a nanostructure. Examples thereof may include, but are not limited to, ZnO, silicon (Si), carbon nanotubes, or the like.

For example, the development of the nanostructure bodies and the developing direction may be controlled using a thermal CVD method, a hydrothermal method, or the like.

Referring to FIG. 3, various piezoelectric materials may be coated on the substrate 10, having the nanostructures 20 thereon, to provide a matrix 30. For example, an organic piezoelectric material of PVDF or an inorganic piezoelectric material of PZT precursor may be coated on the substrate 10. After coating the PZT precursor, the PZT may be cured by a heat treatment. For example, the PZT precursor may be formed using titanium butoxide, zirconium isopropoxide, lead acetate, isopropyl alcohol/methanol, an ammonium solution, or the like, but is not limited thereto.

Then nanostructure bodies 20 may be selectively etched to provide nanopores 40. The nanostructure bodies 20 may be entirely or almost entirely etched while the matrix 30 is not etched or is negligibly etched. For example, a BOE (buffered oxide etchant), phosphoric acid, or the like may be used as an etching solution of ZnO when the nanostructure bodies 20 includes ZnO. As a result, nanopores 40 may be formed without using a process such as photolithography, so the process of manufacturing a piezoelectric device having a nanostructure may be simplified and the cost may be reduced.

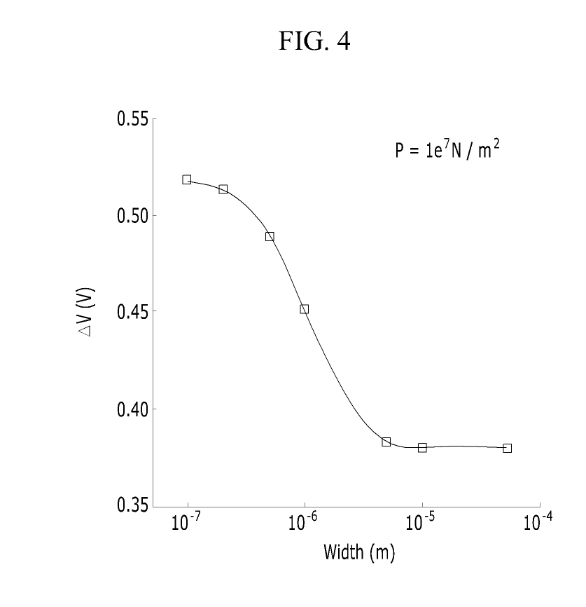

FIG. 4 is a graph showing piezoelectric potential depending upon a gap between nanopores in a piezoelectric device according to an embodiment.

FIG. 4 shows how the amount of potential that is piezoelectrically generated due to a given mechanical stress varies according to a gap between nanopores. The matrix formed with nanopores includes PVDF. The X-axis refers to a gap between nanopores, and the unit is meters, and the Y-axis refers to a peak to peak piezoelectric potential difference, and the unit is volts.

Referring to FIG. 4, it is understood that the piezoelectric potential varies based on the gaps between the nanopores regardless of the thickness of the matrix, the type of piezoelectric material, or the stress applied. In other words, as the gap between nanopores is narrower, the piezoelectric potential increases due to the strain confinement effect of the nanostructures, so that the piezoelectric performance of the piezoelectric device may be improved.

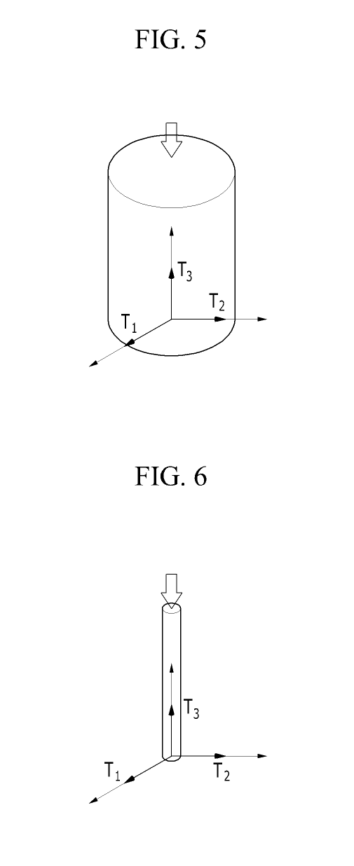

FIG. 5 is a view modeling a piezoelectric device having a bulky structure, and FIG. 6 is a view modeling a piezoelectric device having a nanostructure.

Referring to FIG. 5, the bulky structure is assumed to be a cylindrical structure having a large diameter. In FIG. 5, the stress T1 in the X-direction is same as the stress T2 in Y-direction and has a predetermined value.

Referring to FIG. 6, the nanostructure is assumed to be a cylindrical structure having a small diameter. Since the nanostructure approximates a two-dimensional structure, the strain is limited in the X- and Y-directions, and stresses T1 and T2 are also limited in the X- and Y-directions, wherein T1 and T2 are the same as each other and approach 0.

The piezoelectric coefficient may be defined according to the following Equation 1.

$${d}_{ij} = {( \frac{\partial {D}_{i}}{\partial {T}_{j}} )}^{E} = {( \frac{\partial {S}_{i}}{\partial {E}_{j}} )}^{T} \qquad Equation 1$$

Herein, Dᵢ is the i component of the electric displacement tensor, Tⱼ is the i component of the stress tensor, Sᵢ is the i component of the strain tensor, and Eⱼ is the i component of the electrical field.

In the bulky structure of FIG. 5, the piezoelectric coefficient may be defined as follows in Equation 2.

$$\begin{matrix}{d}_{33 , Bulk}^{eff} ≅ {( \frac{\partial {D}_{3}}{\partial {T}_{3}} )}^{E} \\ = {( \frac{\partial {S}_{3}}{\partial {E}_{3}} )}^{T} \\ = {d}_{33} + {s}_{13}^{E} ( {T}_{1} + {T}_{2} ) / {E}_{3} \\ = {d}_{33} - \frac{2 {s}_{13}^{E}}{{s}_{11}^{E} + {s}_{12}^{E}} {d}_{31}\end{matrix} \qquad Equation 2$$

Herein, dᵢⱼ is a piezoelectric coefficient, and sᵢⱼ^{E} is compliance at a constant electrical field.

In the nanostructure of FIG. 6, when T1 and T2 are 0, the piezoelectric coefficient in the nanostructure has a larger value than the piezoelectric coefficient in the bulky structure as shown, in the following Equation 3. As a result, the piezoelectric coefficient may determine the efficiency of piezoelectric generation, so the piezoelectric generating efficiency in the nanostructure is higher than in the bulky structure.

d_{33,nano}^{eff}≅d₃₃>d_{33,bulk}^{eff} Equation 3

A piezoelectric device having a nanostructure described herein with respect to embodiments may have improved performance. A method according to an embodiment may easily provide a nanostructure of a highly efficient piezoelectric material, which was previously difficult to provide with a nanostructure without a complicated process such as lithography or the like.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A piezoelectric device comprising:
a matrix comprising a piezoelectric material,
wherein at least one nanopore is disposed in the matrix, and the nanopore extends substantially in a first direction.

2. The piezoelectric device of claim 1, wherein the at least one nanopore comprises a plurality of nanopores, and each of the plurality of nanopores extends substantially in the first direction.

3. The piezoelectric device of claim 1, wherein the at least one nanopore has a shape of a nanowire or a nanoribbon.

4. The piezoelectric device of claim 1, wherein the at least one nanopore is hollow.

5. The piezoelectric device of claim 1, wherein the piezoelectric material comprises is lead zirconate titanate of the formula Pb[ZrₓTi₁₋ₓ]O₃ (0<x<1), polyvinylidene fluoride, barium titanate of the formula BaTiO₃, or a mixture thereof.

6. The piezoelectric device of claim 1, wherein the piezoelectric material comprises zinc oxide, silicon, carbon nanotubes, or a mixture thereof.

7. A method of manufacturing a piezoelectric device, the method comprising:
coating a piezoelectric material on a substrate, wherein the substrate has at least one nanostructure body disposed thereon; and
selectively etching the at least one nanostructure body.

8. The method of claim 7, wherein the at least one nanostructure body extends substantially in a first direction.

9. The method of claim 8, wherein the at least one nanostructure body comprises a plurality of nanostructure bodies, and each of the plurality of nanostructure bodies extends substantially in the first direction.

10. The method of claim 7, wherein the at least one nanostructure body has a shape of a nanowire or a nanoribbon.

11. The method of claim 7, wherein the at least one nanostructure body comprises zinc oxide, silicon, carbon nanotubes, or a mixture thereof.

12. The method of claim 7, wherein the at least one nanostructure body comprises a plurality of nanostructure bodies, the coating the piezoelectric material on the substrate forms a matrix, and the selectively etching forms a plurality of nanopores.

13. The method of claim 7, further comprising forming the at least one nanostructure body on the substrate.

14. The method of claim 13, wherein the forming the at least one nanostructure body comprises forming the at least one nanostructure body by one of thermal chemical vapor deposition and a hydrothermal method.

15. The method of claim 7, wherein the piezoelectric material comprises lead zirconate titanate of the formula Pb[ZrₓTi₁₋ₓ]O₃ (0<x<1), polyvinylidene fluoride, barium titanate of the formula BaTiO₃, or a mixture thereof.

16. The method of claim 7, wherein the piezoelectric material comprises zinc oxide, silicon, carbon nanotubes, or a mixture thereof.
